(19) United States
(12) Patent Application Publication
(10) Pub. No.: US 2025/0006272 A1
(43) Pub. Date: Jan. 2, 2025

(54) NONVOLATILE MEMORY DEVICE

(71) Applicant: ROHM CO., LTD., Kyoto-shi (JP)

(72) Inventor: Seiji TAKENAKA, Kyoto-shi (JP)

(21) Appl. No.: 18/886,210

(22) Filed: Sep. 16, 2024

Related U.S. Application Data
(63) Continuation of application No. PCT/JP2023/009331, filed on Mar. 10, 2023.

(30) Foreign Application Priority Data
Mar. 17, 2022 (JP) 2022-042612

(51) Int. Cl. G11C 16/10; G11C 16/28

(52) U.S. Cl. CPC G11C 16/102; G11C 16/28

(57) ABSTRACT

A nonvolatile memory device includes a memory element configured to perform program operation by trapping charges to a sidewall, and a switch configured to widen a drain-source voltage of the memory element during the program operation, with polarity same as polarity during read operation.

### CROSS-REFERENCE TO RELATED APPLICATIONS

This application is a continuation under 35 U.S.C. § 120 of PCT/JP2023/009331 filed on Mar. 10, 2023, which is incorporated herein by reference, which claims priority to Japanese Application No. 2022-042612 filed on Mar. 17, 2022. The present application likewise claims priority under 35 U.S.C. § 119 to Japanese Application No. 2022-042612 filed on Mar. 17, 2022, the entire contents of which is also incorporated herein by reference.

### BACKGROUND

### Technical Field

The present disclosure relates to a nonvolatile memory device.

### Background Art

A nonvolatile memory device using injection of hot carriers into a transistor has been used. The nonvolatile memory device of this type includes first and second transistors aligned in characteristics in an initial state, as memory elements, and changes the characteristics of one of the transistors by injecting hot carriers into the one transistor. In read operation thereafter, based on magnitude relationship of drain currents when a common gate voltage is supplied to the first and second transistors, a signal indicating whether data “0” is stored or data “1” is stored is read out. For example, a state where the drain current of the first transistor is less than the drain current of the second transistor (state where characteristics of the first transistor are changed) corresponds to a state where data “0” is stored, whereas a state where the drain current of the second transistor is less than the drain current of the first transistor (state where characteristics of the second transistor are changed) corresponds to a state where data “1” is stored.

Patent Literature 1 discloses a technique relating to the above.

### CITATION LIST

### Patent Literature

Patent Literature 1: Japanese Patent Application Laid-Open No. 2011-103158

### BRIEF DESCRIPTION OF THE DRAWINGS

FIG. 1 is a diagram illustrating a configuration of a nonvolatile memory device according to a comparative example.

FIG. 2 is a diagram illustrating gate-source voltage dependence of a drain current of a data element.

FIG. 3 is a timing chart illustrating waveform examples of a signal XRST, a voltage V1 of a line Ln1, and a voltage V2 of a line Ln2.

FIG. 4 is a diagram illustrating an example of voltage application to a memory element during program operation.

FIG. 5 is a longitudinal cross-sectional view of a structure of the memory element corresponding to FIG. 4.

FIG. 6 is a diagram illustrating an example of voltage application to memory elements during read operation.

FIG. 7 is a longitudinal cross-sectional view of structures of the memory elements corresponding to FIG. 6.

FIG. 8 is a diagram illustrating a configuration of a nonvolatile memory device according to an embodiment of the present disclosure.

FIG. 9 is a diagram illustrating an example of voltage application to a memory element during program operation.

FIG. 10 is a longitudinal cross-sectional view of a structure of the memory element corresponding to FIG. 9.

FIG. 11 is a diagram illustrating an example of voltage application to memory elements during read operation.

FIG. 12 is a longitudinal cross-sectional view of structures of the memory elements corresponding to FIG. 11.

FIG. 13 is a diagram illustrating gate-source voltage-drain current characteristics in the memory elements illustrated in FIG. 7.

FIG. 14 is a diagram illustrating gage-source voltage-drain current characteristics in the memory elements illustrated in FIG. 12.

FIG. 15 is a diagram illustrating a modification of the configuration illustrated in FIG. 8.

### DETAILED DESCRIPTION

An exemplary embodiment is described below with reference to drawings. A nonvolatile memory device described below may be configured as a semiconductor integrated circuit.

### 1. Comparative Example

### 1-1. Configuration of Nonvolatile Memory Device According to Comparative Example

Before the embodiment of the present disclosure is described, a comparative example is described. The significance of the embodiment of the present disclosure becomes apparent by description of the comparative example.

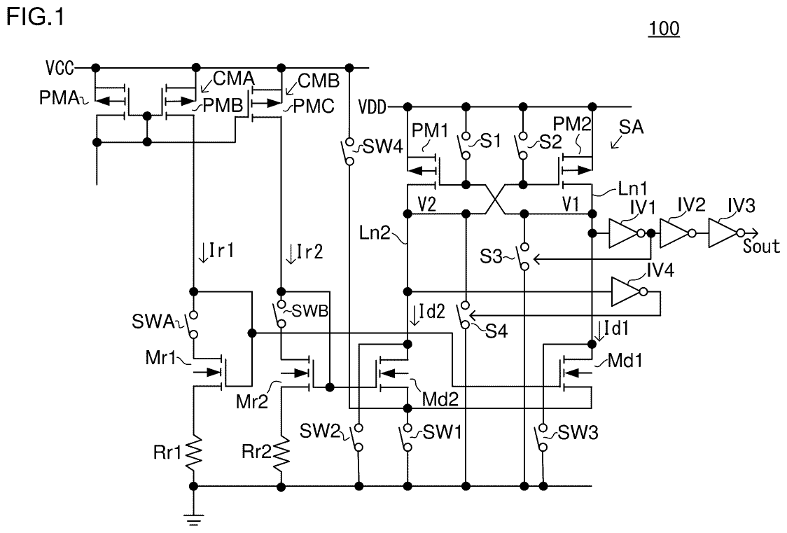

FIG. 1 is a diagram illustrating a configuration of a nonvolatile memory device 100 according to the comparative example. The nonvolatile memory device 100 includes a first reference element Mr1, a second reference element Mr2, a first reference resistor Rr1, a second reference resistor Rr2, a first data element Md1, a second data element Md2, and a sense amplifier SA. The nonvolatile memory device 100 further includes switches SW1 to SW4, switches SWA and SWB, and PMOS transistors PMA to PMC. In FIG. 1, power supply voltage VCC>power supply voltage VDD is established, and for example, VCC=+6.5 V and VDD=+0.5 V are set.

By a combination of the first data element Md1 and the second data element Md2, data “0” or data “1” is stored.

The data elements Md1 and Md2 and the reference elements Mr1 and Mr2 are all configured as memory elements, and more specifically are configured by NMOS transistors (N-channel MOSFETs (Metal-Oxide-Semiconductor Field Effect Transistors)). The memory element is an element that can perform program operation when characteristics of the transistor are changed by injection of hot carries and is also referred to as an OTP (One Time Programmable) element.

A current mirror CMA is configured by PMOS transistors (P-channel MOSFETs) MPA and MPB. Sources of the PMOS transistors PMA and PMB are connected to an application end of the power supply voltage VCC.

A gate of the first reference element Mr1 is connected to a drain of the PMOS transistor PMB. The switch SWA is connected between the drain of the PMOS transistor PMB and a drain of the first reference element Mr1. A source of the first reference element Mr1 is connected to one end of the first reference resistor Rr1. The other end of the first reference resistor Rr1 is connected to a ground end (application end of ground potential).

A gate of the first data element Md1 is connected to the gate of the first reference element Mr1. A drain of the first data element Md1 is connected to one of input ends of the sense amplifier SA.

A current mirror CMB is configured by the PMOS transistors PMA and PMC. Sources of the PMOS transistors PMA and PMC are connected to the application end of the power supply voltage VCC.

A gate of the second reference element Mr2 is connected to a drain of the PMOS transistor PMC. The switch SWB is connected between the drain of the PMOS transistor PMC and a drain of the second reference element Mr2. A source of the second reference element Mr2 is connected to one end of the second reference resistor Rr2. The other end of the second reference resistor Rr2 is connected to the ground end.

A gate of the second data element Md2 is connected to the gate of the second reference element Mr2. A drain of the second data element Md2 is connected to the other input end of the sense amplifier SA.

A source of the first data element Md1 and a source of the second data element Md2 are connected to one end of the switch SW1. The other end of the switch SW1 is connected to the ground end.

As described above, a current mirror is configured by the first reference element Mr1 and the first data element Md1, and a current mirror is configured by the second reference element Mr2 and the second data element Md2.

The drain of the data element Md1 is connected to one end of the switch SW3. The other end of the switch SW3 is connected to the ground end. The drain of the data element Md2 is connected to one end of the switch SW2. The other end of the switch SW2 is connected to the ground end. The source of the data element Md1 and the source of the data element Md2 are connected to one end of the switch SW4. The other end of the switch SW4 is connected to the application end of the power supply voltage VCC.

The first reference resistor Rr1 and the second reference resistor Rr2 have the same resistance value. The data elements Md1 and Md2 and the reference elements Mr1 and Mr2 have the same configuration and have the same electric characteristics before execution of program operation. Targets of the program operation are the data elements Md1 and Md2. Therefore, before execution of the program operation, the data elements Md1 and Md2 and the reference elements Mr1 and Mr2 have the same gate threshold voltage.

It is assumed that the switch SW1 is in an on state, each of the switches SW2 to SW4 is in an off state, and each of the switches SWA and SWB is in the on state. A gate-source voltage Vgs of the first data element Md1 is a voltage obtained by adding a voltage generated between both ends of the first reference resistor Rr1 to a gate-source voltage Vgs of the first reference element Mr1. A gate-source voltage Vgs of the second data element Md2 is a voltage obtained by adding a voltage generated between both ends of the second reference resistor Rr2 to a gate-source voltage Vgs of the second reference element Mr2.

Accordingly, before execution of the program operation in the data elements Md1 and Md2, magnitude relationship of drain currents Id1 and Id2 respectively flowing through the data elements Md1 and Md2 and drain currents Ir1 and Ir2 respectively flowing through the reference elements Mr1 and Mr2 are Id1>Ir1 and Id2>Ir2. Further, Ir1=Ir2 is established, and Id1=Id2 is established. Accordingly, the currents flowing through the data elements Md1 and M2 are not different from each other, and data is indefinite. In other words, in the nonvolatile memory device 100 having this configuration, an initial value of data in a state where the program operation is not performed on the data elements Md1 and Md2 is not set.

Regarding a transistor, a structure is a concept including a size of the transistor, and accordingly, the optional plurality of transistors having the same structure means that the sizes of the plurality of transistors are equal to each other. When the certain plurality of transistors have the same structure, if hot carrier injection by program operation is not performed on the plurality of transistors, the plurality of transistors have the same electric characteristics (including gate threshold voltage, etc.). However, the optional plurality of transistors having the same structure, and the same electric characteristics means that they are designed to be the same, and they may actually include some tolerance (i.e., same is understood as concept including some tolerance).

In the nonvolatile memory device 100, read operation for reading out data stored in the data elements Md1 and Md2, and program operation (write operation) for rewriting data (logical values) stored in the data elements Md1 and Md2 are performable. During the read operation, the switch SW1 is in the on state, the switches SW2 to SW4 are in the off state, and the switches SWA and SWB are in the on state.

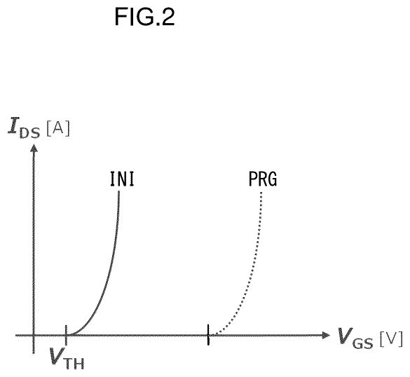

During the program operation, hot carriers are injected into the data elements Md1 and Md2 to change the electric characteristics of the data elements Md1 and Md2. By the change, gate threshold voltages of the data elements Md1 and Md2 are increased. In FIG. 2, a solid-line waveform INI indicates gate-source voltage dependence of the drain current of the data elements Md1 and Md2 before execution of the program operation, and a dotted-line waveform PRG indicates gate-source voltage dependence of the drain current of the data elements Md1 and Md2 after execution of the program operation. As illustrated, a gate threshold voltage Vth is increased by the program operation.

The program operation is performed when the power supply voltage VCC is supplied to the gates of the data elements Md1 and Md2, the power supply voltage VCC is supplied to the sources, and the ground potential (0 V) is applied to the drains. During the program operation, the switch SW1 is in the off state, the switches SW2 to SW4 are in the on state, and the switches SWA and SWB are in the off state.

In a state where the drain currents Ir1 and Ir2 are supplied, the sense amplifier SA outputs an output signal Sout corresponding to the values (logic values) of the stored data based on the magnitude relationship of the drain currents Id1 and Id2 of the data elements Md1 and Md2 during the read operation.

By execution of the program operation, hot carriers are injected into the first data element Md1 of the data elements Md1 and Md2 before execution of the program operation, which increases the gate threshold voltage of the first data element Md1. As a result, after execution of the program operation, the gate threshold voltage of the first data element Md1 is higher than the gate threshold voltage of the second data element Md2. Therefore, the magnitude relationship of the drain currents Id1 and Id2 becomes Id1<Id2. The state where the drain current Id1 is less than the drain current Id2 corresponds to a state where data “0” is stored. Therefore, during the read operation, when the drain current Id1 is less than the drain current Id2, the sense amplifier SA outputs the output signal Sout (low-level Sout) corresponding to the data “0”.

In contrast, by execution of the program operation, hot carriers are injected into the second data element Md2 of the data elements Md1 and Md2 before execution of the program operation, which increases the gate threshold voltage of the second data element Md2. As a result, after execution of the program operation, the gate threshold voltage of the second data element Md2 is higher than the gate threshold voltage of the first data element Md1. Therefore, the magnitude relationship of the drain currents Id1 and Id2 becomes Id1>Id2. The state where the drain current Id1 is greater than the drain current Id2 corresponds to a state where data “1” is stored. Therefore, during the read operation, when the drain current Id1 is greater than the drain current Id2, the sense amplifier SA outputs the output signal Sout (high-level Sout) corresponding to the data “1”.

As illustrated in FIG. 1, the sense amplifier SA includes PMOS transistors (P-channel MOSFETs) PM1 and PM2, switches S1 and S2, switches S3 and S4, and inverters IV1 to IV4.

A source of the PMOS transistor PM2 is connected to an application end of the power supply voltage VDD. A drain of the PMOS transistor PM2 is connected to a line Ln1. A gate of the PMOS transistor PM2 is connected to a line Ln2. The line Ln1 is connected to the drain of the first data element Md1. The line Ln2 is connected to the drain of the second data element Md2.

A source of the PMOS transistor PM1 is connected to the application end of the power supply voltage VDD. A drain of the PMOS transistor PM1 is connected to the line Ln2. A gate of the PMOS transistor PM1 is connected to the line Ln1.

The switch S1 is connected between the application end of the power supply voltage VDD and the line Ln1. The switch S2 is connected between the application end of the power supply voltage VDD and the line Ln2.

An input end of the inverter IV1 is connected to the line Ln1. An output end of the inverter IV1 is connected to an input end of the inverter IV2. An output end of the inverter IV2 is connected to an input end of the inverter IV3. The output signal Sout is output from the inverter IV3.

The switch S3 is connected between the line Ln1 and the ground end. On/off of the switch S3 is controlled based on an output of the inverter IV1. The switch S4 is connected between the line Ln2 and the ground end. An input end of the inverter IV4 is connected to the line Ln2. On/off of the switch S4 is controlled based on an output of the inverter IV4.

A control circuit (not illustrated) can output a signal XRST, and controls on/off of the switches S1 and S2.

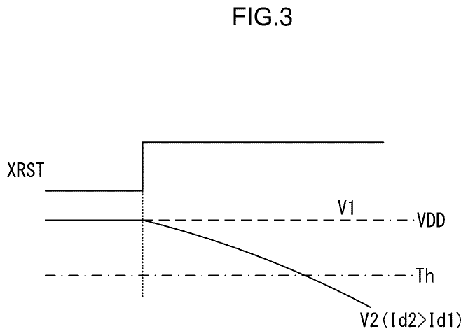

FIG. 3 is a timing chart illustrating waveform examples of the signal XRST, a voltage V1 of the line Ln1, and a voltage V2 of the line Ln2. Operation of the sense amplifier SA is described also with reference to FIG. 3. During the read operation, a period when the signal XRST is at a low level is referred to as a pre-charge period, and a period when the signal XRST is at a high level is referred to as a read period.

In the pre-charge period that is the period when the signal XRST is at the low level, the drain currents Ir1 and Ir2 are turned off, and the switches S1 and S2 are turned on. Accordingly, the gate and the source of each of the PMOS transistors PM1 and PM2 are short-circuited, and the PMOS transistors PM1 and PM2 are turned off. Further, positive charges are supplied to the line Ln1 through the switch S1 that is turned on, and the voltage V1 reaches the level of the power supply voltage VDD. Positive charges are supplied to the line Ln2 through the switch S2 that is turned on, and the voltage V2 also reaches the level of the power supply voltage VDD. At this time, the outputs of the inverters IV1 and IV4 are at the low level, and the switches S3 and S4 are accordingly turned off.

When the signal XRST is switched from the low level to the high level, and the period shifts from the pre-charge period to the read period, the drain currents Ir1 and Ir2 are turned on, and the switches S1 and S2 are turned off. In a case where the drain current Id2 flows, the voltage V2 is lowered, whereas in a case where the drain current Id1 flows, the voltage V1 is lowered.

In the read operation after the program operation is performed on the first data element Md1, Id1=0 and Id2>Id1 are established, and thus, the voltage V2 is lowered (V2 (Id2>Id1) in FIG. 3). When the voltage V2 reaches a threshold Th, the output of the inverter IV4 is switched from the low level to the high level, and the switch S4 is turned on. As a result, the voltage V2=0 V is achieved, the PMOS transistor PM2 is turned on, and the voltage V1=VDD is achieved. At this time, the PMOS transistor PM1 is turned off. Accordingly, the output signal Sout output from the inverter IV3 is at the low level. In other words, the output signal Sout is output as a signal indicating a state where “0” is stored.

On the other hand, in the read operation after the program operation is performed on the second data element Md2, Id2=0 and Id2<Id1 are established, and thus, the voltage V1 is lowered. When the voltage V1 reaches the threshold Th, the output of the inverter IV1 is switched from the low level to the high level, and the switch S3 is turned on. As a result, the voltage V1=0 V is achieved, the PMOS transistor PM1 is turned on, and the voltage V2=VDD is achieved. At this time, the PMOS transistor PM2 is turned off. Accordingly, the output signal Sout output from the inverter IV3 is at the high level. In other words, the output signal Sout is output as a signal indicating a state where “1” is stored.

### 1-2. Issues in Comparative Example

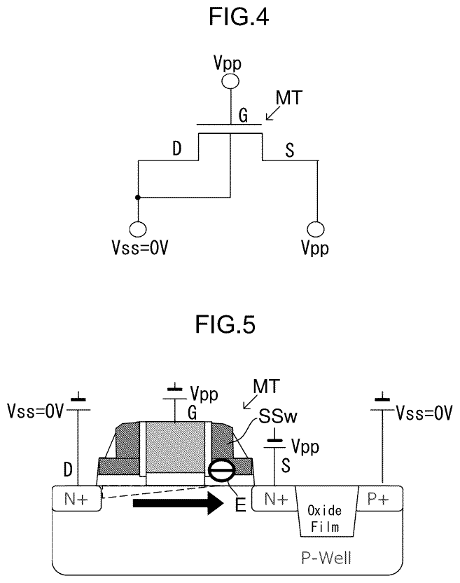

FIG. 4 is a diagram illustrating voltage application to a memory element MT (NMOS transistor) during the program operation. FIG. 5 is a longitudinal cross-sectional view of a structure of the memory element MT corresponding to FIG. 4. The memory element MT is used for the above-described data elements Md1 and Md2 (FIG. 1).

As illustrated in FIG. 4 and FIG. 5, during the program operation, a high voltage Vpp is applied to a gate G of the memory element MT, the high voltage Vpp is applied to a source S, and a ground potential Vss (=0 V) is applied to a drain D. The high voltage Vpp is, for example, +6.5 V, and in the configuration illustrated in FIG. 1, Vpp=VCC is established.

By such voltage application, as illustrated by an arrow in FIG. 5, hot carriers (electrons) flowing from the drain D to the source S are generated just below the gate G. The hot carriers are drawn to the high voltage Vpp (positive voltage) applied to the gate G, and are trapped to a sidewall SSw on the source S side provided along a side surface of the gate G (trapped hot carrier E is illustrated in FIG. 5).

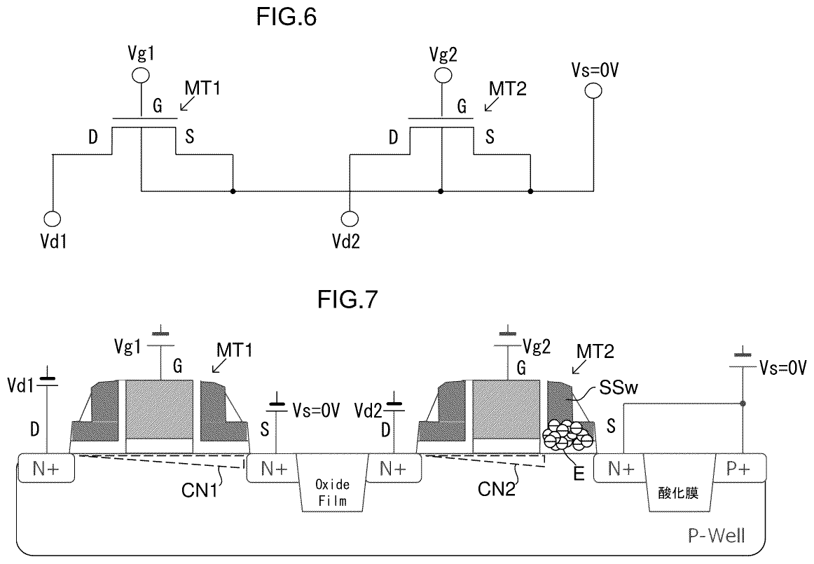

FIG. 6 is a diagram illustrating voltage application to memory elements MT1 and MT2 (NMOS transistors) during the read operation. FIG. 7 is a longitudinal cross-sectional view of structures of the memory elements MT1 and MT2 corresponding to FIG. 6. The memory elements MT1 and MT2 respectively correspond to the above-described data elements Md1 and Md2 (FIG. 1).

As illustrated in FIG. 6 and FIG. 7, during the read operation, gate voltages Vg1 and Vg2 are applied to respective gates G of the memory elements MT1 and MT2, drain voltages Vd1 and Vd2 are applied to respective drains D, and a ground potential Vs (=0 V) is applied to sources. The gate voltages Vg1 and Vg2 are, for example, 2 V. The drain voltages Vd1 and Vd2 are, for example, +0.5 V.

FIG. 6 and FIG. 7 illustrate, as an example, a case where the memory element MT1 is in a state before execution of the program operation (program non-operation state) and the memory element MT2 is in a state after execution of the program operation. In other words, the memory element MT2 is equivalent to the memory element MT illustrated in FIG. 4 and FIG. 5.

As illustrated in FIG. 7, in the memory element MT2 after execution of the program operation, the hot carriers E are trapped to the sidewall SSw. Therefore, an electric field by the gate voltage Vg2 does not reach just below the sidewall SSw, and a channel CN2 is interrupted on the source S side. Therefore, the gate threshold voltage is increased, and the drain current is hard to flow.

On the other hand, as illustrated in FIG. 7, the memory element MT1 before execution of the program operation is in the on state, and the drain current flows.

In a case where the memory element performing the program operation by such a method is used for the nonvolatile memory device, as illustrated in FIG. 1, the switches SW2 and SW3 for applying the ground potential to the drains of the memory elements, the switch SW4 for applying the high voltage to the sources of the memory elements, and the switch SW1 for isolating the sources from the ground potential when the high voltage is applied to the sources are necessary, which causes an issue that a size of the circuit for program operation is increased. In particular, to handle the large drain current flowing during the program operation, it is necessary to increase the sizes of the switches SW2 to SW4.

### 2. Embodiment of Present Disclosure

### 2-1. Configuration of Nonvolatile Memory Device According to Present Disclosure

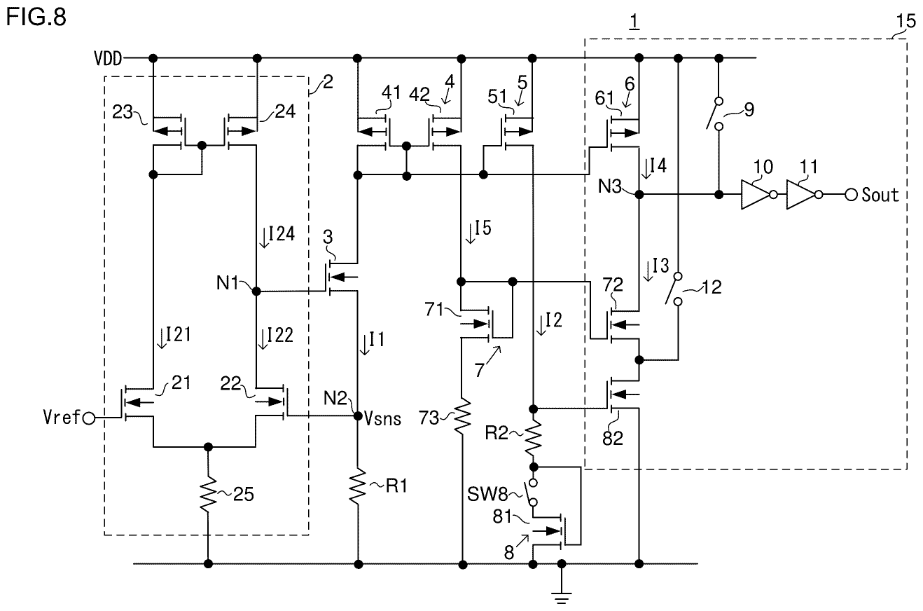

To solve the above-described issue, the embodiment of the present disclosure is implemented. The embodiment of the present disclosure is described below. FIG. 8 is a diagram illustrating a configuration of a nonvolatile memory device 1 according to the embodiment of the present disclosure.

The nonvolatile memory device 1 includes a differential amplifier 2, a drive transistor 3, current mirrors 4 to 8, a switch 9, inverters 10 and 11, and a switch 12. The switch 12 is in the off state during the read operation. In FIG. 8, the power supply voltage VDD is, for example, VDD=+6.5 V.

The differential amplifier 2 includes input transistors 21 and 22, PMOS transistors 23 and 24, and a resistor element 25. The input transistors 21 and 22 are configured by NMOS transistors. A reference voltage Vref is applied to a gate of the input transistor 21. A source of the input transistor 21 is connected to one end of the resistor element 25. A drain of the input transistor 21 is connected to a drain of the PMOS transistor 23. A gate and the drain of the PMOS transistor 23 are short-circuited. A source of the PMOS transistor 23 is connected to an application end of the power supply voltage VDD. A gate of the PMOS transistor 24 is connected to the gate of the PMOS transistor 23. A source of the PMOS transistor 24 is connected to the application end of the power supply voltage VDD. A drain of the PMOS transistor 24 is connected to a drain of the input transistor 22. A source of the input transistor 22 is connected to the one end of the resistor element 25. The other end of the resistor element 25 is connected to a ground end.

The drive transistor 3 is configured by an NMOS transistor. A node N1 at which the PMOS transistor 24 and the input transistor 22 are connected is connected to a gate of the drive transistor 3. A source of the drive transistor 3 is connected to one end of a resistor element R1. The other end of the resistor element R1 is connected to the ground end. A node N2 at which the drive transistor 3 and the resistor element R1 are connected is connected to a gate of the input transistor 22.

In the differential amplifier 2, a current I21 corresponding to the reference voltage Vref flows through the input transistor 21. The current I21 is mirrored by a current mirror including the PMOS transistors 23 and 24 to be turned into a current I24 flowing through the PMOS transistor 24. A current I22 corresponding to a sense voltage Vsns generated at the node N2 flows through the input transistor 22. The gate of the drive transistor 3 is driven based on the balance of the currents I24 and I22, and an on-resistance of the drive transistor 3 is adjusted. In other words, the differential amplifier 2 drives the gate of the drive transistor 3 based on a difference between the reference voltage Vref and the sense voltage Vsns. As a result, the sense voltage Vsns is controlled so as to be coincident with the reference voltage Vref. A constant voltage circuit that makes the sense voltage Vsns constant is configured by the differential amplifier 2, the drive transistor 3, and the resistor element R1.

The current mirror 4 includes an input-side transistor 41 and an output-side transistor 42 that are configured by PMOS transistors. The current mirror 5 includes the input-side transistor 41 and an output-side transistor 51 that are configured by PMOS transistors. The current mirror 6 includes the input-side transistor 41 and an output-side transistor 61 that are configured by PMOS transistors. In other words, the input-side transistor 41 is common to the current mirrors 4, 5, and 6.

The current mirror 8 includes a reference element 81, a data element 82, a resistor element R2, and a switch SW8. The reference element 81 and the data element 82 are memory elements (OTP elements) configured by NMOS transistors. As described above, the memory element is an element that can perform program operation. The data element 82 is an object of the program operation.

A drain of the drive transistor 3 is connected to the input-side transistor 41 of the current mirror 5 (current mirrors 4 and 6). The output-side transistor 51 of the current mirror 5 is connected to one end of the resistor element R2.

A gate of the reference element 81 is connected to the other end of the resistor element R2. The switch SW8 is connected between the other end of the resistor element R2 and a drain of the reference element 81. A source of the reference element 81 is connected to the ground end. A gate of the data element 82 is connected to the one end of the resistor element R2. A source of the data element 82 is connected to the ground end.

A drain of the data element 82 is connected to the output-side transistor 61 of the current mirror 6 at a node N3 through an output-side transistor 72 included in a current mirror 7 described below.

A current I1 generated by the sense voltage Vsns and the resistor element R1 is mirrored by the current mirror 5 to be turned into a current I2. When the switch SW8 is in the on state, the current I2 flows through the reference element 81 and the resistor element R2. A gate-source voltage Vgs of the data element 82 is a voltage obtained by adding a voltage generated between both ends of the resistor element R2 to a gate-source voltage Vgs of the reference element 81. The resistor element R2 is an example of a voltage addition unit adding a voltage. The voltage addition unit is not limited to the resistor element, and may be configured by, for example, an MOS transistor.

The reference element 81 and the data element 82 have the same structure and have the same electric characteristics before execution of the program operation. Therefore, in a state before the program operation is performed on the data element 82 (both reference element 81 and data element 82 are in program non-operation state), a current I3 flowing through the data element 82 satisfies I3>I2.

On the other hand, the current I1 is mirrored by the current mirror 6 to be turned in to a current I4. The current I4 flowing through the output-side transistor 61 of the current mirror 6 serves as a reference current. In other words, the output-side transistor 61 is an example of a reference current generation unit. For example, when I1=I2=I4=1 μA is set, I3=3 μA is achieved in a state before the program operation is performed on the data element 82.

The node N3 is connected to an input end of the inverter 10. An input end of the inverter 11 is connected to an output end of the inverter 10. The output signal Sout is output from an output end of the inverter 11.

The switch 9 is connected between the application end of the power supply voltage VDD and the node N3. In a reset state where the switch 9 is in the on state, a voltage at the input end of the inverter 10 is fixed to the high level, and the output signal Sout is fixed to the high level. When the switch 9 is switched from the reset state to the off state, I3>I4 is achieved in a state before the program operation is performed on the data element 82, the current is drawn to the node N3, and the voltage at the input end of the inverter 10 is lowered to the low level. For example, in a case of the above-described example of the current value, since I3=3 μA and I4=1 μA are established. Therefore, the current of 2 μA is drawn to the node N3. As a result, the output signal Sout output from the inverter 11 becomes the low level. In other words, the output signal Sout is output as a signal indicating a state where “0” is stored.

On the other hand, in a state after the program operation is performed on the data element 82, a gate threshold voltage of the data element 82 is increased and I3=0 is achieved. When the switch 9 is switched from the reset state to the off state, I4>I3 is achieved in the state after the program operation is performed on the data element 82, and the voltage at the input end of the inverter 10 is maintained at the high level. Accordingly, the output signal Sout output from the inverter 11 becomes the high level. In other words, the output signal Sout is output as a signal indicating a state where “1” is stored.

As described above, in the present embodiment, in the state before the program operation is performed on the data element 82, the current I3 greater than the current I4 as the reference current is generated by the current mirror 8, and in the state after the program operation is performed on the data element 82, I3<I4 is achieved. Further, magnitude relationship of the currents I3 and I4 is detected by the inverters 10 and 11, thereby reading out 1-bit data.

The nonvolatile memory device 1 includes a storage circuit 15. The storage circuit 15 includes the data element 82, the output-side transistor 72, the output-side transistor 61, the switch 9, the inverters 10 and 11, and the switch 12. As described above, in the present embodiment, the storage circuit 15 corresponding to 1-bit data can be downsized. The nonvolatile memory device 1 actually corresponds to a plurality of bits (e.g., 32 bits), and the storage circuit 15 is provided for each of the plurality of bits. The configuration illustrated in FIG. 8 other than the storage circuit 15 is a circuit (common circuit) common to the plurality of bits.

In the present embodiment, a voltage added to the gate-source voltage Vgs of the reference element 81 is set with high accuracy by the constant voltage circuit that makes the sense voltage Vsns constant, the current mirror 5, and the resistor elements R1 and R2. For example, when the resistor element R2 is set to have a resistance value that is half of the resistance value of the resistor element R1, the added voltage described above can be set to a half voltage of the sense voltage Vsns.

If the switch 9 is connected between the node N3 and the ground end, in the case where the switch 9 is switched from the reset state to the off state, the voltage at the input end of the inverter 10 rises from the low level to the high level by the current I4 (e.g., 1 μA) as the reference current in the state after the program operation is performed on the data element 82. In contrast, in the present embodiment, since the switch 9 is connected between the application end of the power supply voltage VDD and the node N3, in the case where the switch 9 is switched from the reset state to the off state, the voltage at the input end of the inverter 10 lowers from the high level to the low level by the current (e.g., I3−I4=2 μA) drawn to the node N3 in the state before the program operation is performed on the data element 82. Therefore, since the current drawn to the node N3 is greater than the current I4, a readout time can be shortened.

The configuration is not limited to the configuration illustrated in FIG. 8. In the current mirror 8, a size of the data element 82 may be made larger than a size of the reference element 81 (size of data element 82: size of reference element 81=M:1 (M>1)). In this case, the resistor element R2 is unnecessary. Even with such a configuration, in the state before the program operation is performed on the data element 82, it is possible to cause the current I3 greater than the current I2 to flow and to achieve I3>I4.

### 2-2. Program Operation

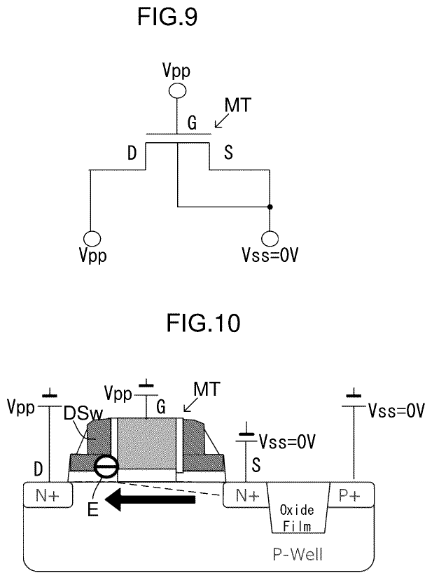

The program operation on the memory element according to the present embodiment is described. FIG. 9 is a diagram illustrating voltage application to the memory element MT (NMOS transistor) during the program operation. FIG. 10 is a longitudinal cross-sectional view of the structure of the memory element MT corresponding to FIG. 9. The memory element MT is used for the above-described data element 82 (FIG. 8).

As illustrated in FIG. 9 and FIG. 10, during the program operation, the high voltage Vpp is applied to the gate G of the memory element MT, the high voltage Vpp is applied to the drain D, and the ground potential Vss (=0 V) is applied to the source S. The high voltage Vpp is, for example, +6.5 V, and in the configuration illustrated in FIG. 8, Vpp=VDD is established.

By such voltage application, as illustrated by an arrow in FIG. 10, hot carriers (electrons) flowing from the source S to the drain D are generated just below the gate G. The hot carriers are drawn to the high voltage Vpp (positive voltage) applied to the gate G and are trapped to a sidewall DSw on the drain D side provided along a side surface of the gate G (trapped hot carrier E is illustrated in FIG. 10).

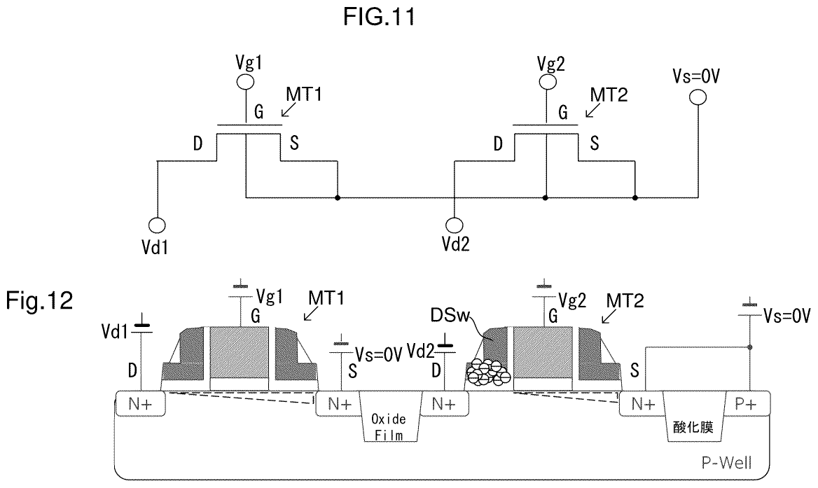

FIG. 11 is a diagram illustrating voltage application to the memory elements MT1 and MT2 (NMOS transistors) during the read operation. FIG. 12 is a longitudinal cross-sectional view of the structures of the memory elements MT1 and MT2 corresponding to FIG. 11.

As illustrated in FIG. 11 and FIG. 12, during the read operation, the gate voltages Vg1 and VG2 are applied to the respective gates G of the memory elements MT1 and MT2, the drain voltages Vd1 and Vd2 are applied to the respective drains D, and the ground potential Vs (=0 V) is applied to the sources.

FIG. 11 and FIG. 12 illustrate, as an example, a case where the memory element MT1 is in the state before execution of the program operation (program non-operation state) and the memory element MT2 is in the state after execution of the program operation. Therefore, the drain-source voltage of the memory element MT2 is the high voltage (Vpp) during the program operation, is Vd2 (<Vpp) during the read operation, and is widened during the program operation with the polarity same as the polarity during the read operation.

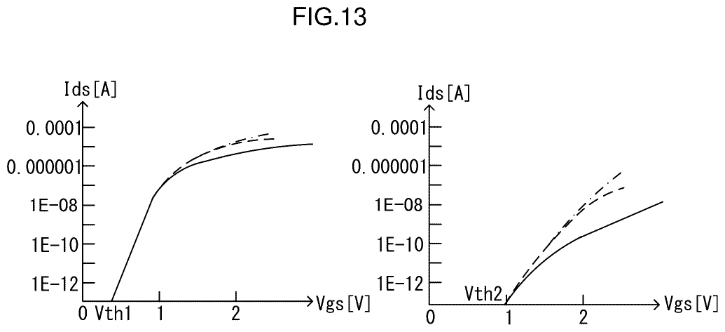

A left part in FIG. 13 illustrates an example of gate voltage Vgs-drain current Ids characteristics of the memory element MT1 (in program non-operation state) according to the above-described comparative example, and a right part in FIG. 13 illustrates an example of gate voltage Vgs-drain current Ids characteristics of the memory element MT2 (in state after execution of program operation) according to the above-described comparative example. In FIG. 13, characteristics in a case where the drain voltage Vd is varied are illustrated. The characteristics in a case of Vd=0.1 V are illustrated by a solid line, the characteristics in a case of Vd=0.5 V are illustrated by a dashed line, and the characteristics in a case of Vd=1.0 V are illustrated by an alternate long and short dash line.

In the memory element MT2 in the state after execution of the program operation (FIG. 7), the charges are trapped to the sidewall SSw on the source side. Therefore, the resistance on the source side is increased, and the drain current is hard to flow as compared with the memory element MTI in the program non-operation state, irrespective of the drain voltage Vd. As illustrated in FIG. 13, irrespective of the drain voltage Vd, a gate threshold voltage Vth2 of the memory element MT2 is higher than a gate threshold voltage Vth1 of the memory element MT1.

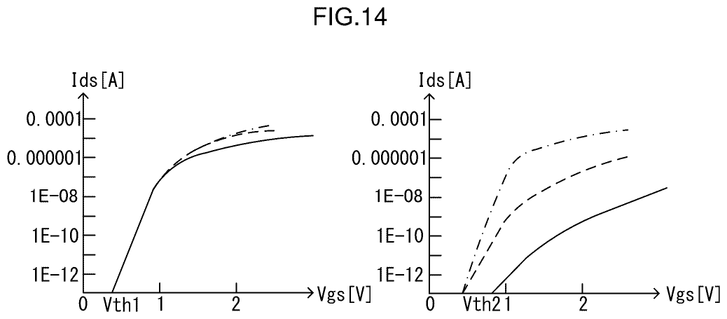

A left part in FIG. 14 illustrates an example of gate voltage Vgs-drain current Ids characteristics of the memory element MTI (in program non-operation state) according to the embodiment of the present disclosure, and a right part in FIG. 14 illustrates an example of gate voltage Vgs-drain current Ids characteristics of the memory element MT2 (in state after execution of program operation) according to the embodiment of the present disclosure. In FIG. 14, characteristics in a case where the drain voltage Vd is varied are illustrated. The characteristics in a case of Vd=0.1 V are illustrated by a solid line, the characteristics in a case of Vd=0.5 V are illustrated by a dashed line, and the characteristics in a case of Vd=1.0 V are illustrated by an alternate long and short dash line.

In the memory element MT2 in the state after execution of the program operation (FIG. 12), in a state before pinch-off (channel block near drain D) occurs at Vd<1.0 V, the drain current is hard to flow due to influence of the charges trapped to the sidewall DSw. Therefore, as illustrated in FIG. 14, at Vd=0.5 V and 0.1 V, the drain current of the memory element MT2 is less than the drain current of the memory element MT1. As illustrated in FIG. 14, at Vd=0.1 V, the gate threshold voltage Vth2 of the memory element MT2 is higher than the gate threshold voltage Vth1 of the memory element MT1.

On the other hand, in the memory element M2, in a state where pinch-off occurs at Vd≥1.0 V, influence of the charges trapped to the sidewall DSw disappears, and the drain current is substantially equal to the drain current of the memory element MT1 in the program non-operation state.

As described above, in the present embodiment, unlike the comparative example, although the program operation is performed by applying the high voltage to the drain D side, when the drain voltage Vd is set to the low voltage (e.g., 0.1 V) during the read operation, it is possible to reduce the drain current as compared with the program non-operation state, and to read out the data.

Therefore, in the present embodiment, the switch 12 is provided in the configuration of the nonvolatile memory device 1 illustrated in FIG. 8. One end of the switch 12 is connected to the application end of the power supply voltage VDD. The other end of the switch 12 is connected to the drain of the data element 82. During the program operation, turning on the switch 12 makes it possible to apply the high voltage (VDD) to the drain of the data element 82. Note that turning on the switch 12 makes it possible to turn off the output-side transistor 72 described below. During the read operation, the switch 12 is turned off. Note that, during the program operation, the high voltage (VDD) is applied to the gate of the data element 82 by turning off the switch SW8. At this time, the voltage VDD is applied to the gate of the reference element 81 and the reference element 81 is turned on. Thus, the ground potential is applied to the drain of the reference element 81 as with the source. Accordingly, it is possible to prevent the reference element 81 from being slightly programmed and being changed in characteristics.

As described above, in the present embodiment, it is sufficient to provide the switch 12 as the switch for performing the program operation on the data element 82. This makes it possible to reduce the circuit size as compared with a case where switches equivalent to the switches SW1 to SW4 (FIG. 1) according to the above-described comparative example are provided.

### 2-3. Low Voltage Control

The current mirror 7 is described. The current mirror 7 is provided to control the drain voltage of the data element 82 to a low voltage. The current mirror 7 includes an input-side transistor 71, the output-side transistor 72, and a resistor element 73.

The input-side transistor 71 and the output-side transistor 72 are configured by NMOS transistors. A gate and a drain of the input-side transistor 71 are short-circuited. The drain of the input-side transistor 71 is connected to the output-side transistor 42 of the current mirror 4. A source of the input-side transistor 71 is connected to one end of the resistor element 73. The other end of the resistor element 73 is connected to the ground end. A gate of the output-side transistor 72 is connected to the gate of the input-side transistor 71. A source of the output-side transistor 72 is connected to the drain of the data element 82. A drain of the output-side transistor 72 is connected to the node N3.

The current I1 is mirrored by the current mirror 4 to be turned into a current I5. The current I5 flows through the input-side transistor 71 and the resistor element 73. A voltage lowered by a gate-source voltage Vgs of the output-side transistor 72 from the voltage obtained by adding a voltage generated between both ends of the resistor element 73 to a gate-source voltage Vgs of the input-side transistor 71 is applied as a drain voltage of the data element 82.

In the present embodiment, by the constant voltage circuit that makes the sense voltage Vsns constant, the current mirror 4, and the resistor elements R1 and 73, a resistance ratio of the resistor element R1 and the resistor element 73 is set to set the voltage generated between the both ends of the resistor element 73 with high accuracy, which makes it possible to control the drain voltage of the data element 82 to the low voltage with high accuracy.

### 2-4. Modification

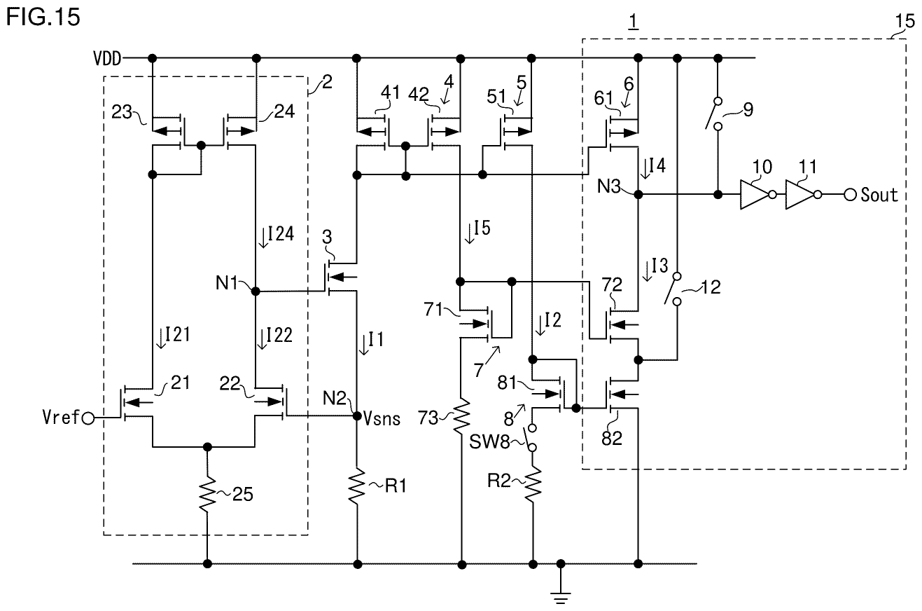

FIG. 15 is a diagram illustrating a modification of the configuration illustrated in FIG. 8 described above. In FIG. 15, as compared with FIG. 8, the configuration of the current mirror 8 is different. More specifically, the gate and the drain of the reference element 81 are short-circuited, and the drain is connected to the output-side transistor 51. The switch SW8 is connected between the source of the reference element 81 and the one end of the resistor element R2. The other end of the resistor element R2 is connected to the ground end. The gate of the data element 82 is connected to the gate of the reference element 81. The switch SW8 is turned on during the read operation and is turned off during the program operation.

### 3. Others

Various technical features disclosed in the present specification can be variously modified without departing from the spirit of the technical ingenuity, in addition to the above-described embodiment. In other words, the above-described embodiment should be considered to be illustrative in all respects and not restrictive, and it should be understood that the technical scope of the present disclosure is not limited to the above-described embodiment and encompasses any modifications in the sense and scope equivalent to those of the claims.

For example, the reference element 81 and the data element 82 are not limited to the NMOS transistors and can be configured by PMOS transistors. In a case where the reference element 81 and the data element 82 are configured by the PMOS transistors, the elements other than the reference element 81 and the data element 82 are appropriately changed in the connection relationships.

### 4. Supplement

As described above, for example, a nonvolatile memory device (1) according to the present disclosure includes:
a memory element (82) configured to perform program operation by trapping charges to a sidewall; and
a switch (12) configured to widen a drain-source voltage of the memory element during the program operation, with polarity same as polarity during read operation (first configuration).

In the above-described first configuration, the memory element (82) is an NMOS transistor, and the switch (12) is connected between an application end of a power supply voltage (VDD) and a drain of the memory element (second configuration).

The above-described first or second configuration may further include a first current mirror (7) including a first input-side transistor (71), a first output-side transistor (72) connected to the drain of the memory element (82), and a first resistor (73) connected to the first input-side transistor (third configuration).

The above-described third configuration may further include:
a second resistor (R1);
a constant voltage circuit configured to make a voltage (Vsns) applied to the second resistor constant; and
a second current mirror (4) including a second input-side transistor (41) connected to the second resistor, and a second output-side transistor (42) connected to the first input-side transistor (71) (fourth configuration).

In the fourth configuration, the constant voltage circuit may include a drive transistor (3), the second resistor (R1) connected to the drive transistor, and a differential amplifier (2) configured to drive the drive transistor based on a difference between a reference voltage (Vref) and a sense voltage (Vsns) generated at a first node (N2) at which the drive transistor and the second resistor are connected (fifth configuration).

Any of the above-described first to fifth configurations may further include:
a third current mirror (8) including a reference element (81) and the data element (82);
a reference current generation unit (61) connected to the data element and configured to generate a reference current (I4); and
a storage circuit (I5) including the data element and the reference current generation unit,
in which, in the storage circuit, data is read out data based on magnitude relationship of a current (I3) flowing through the data element and the reference current (sixth configuration).

### INDUSTRIAL APPLICABILITY

The present disclosure can be used for, for example, a nonvolatile memory device mounted on various kinds of semiconductor apparatuses.

### REFERENCE SIGNS LIST

1 Nonvolatile memory device
2 Differential Amplifier
3 Drive transistor
4 to 8 Current mirror
9 Switch
10, 11 Inverter
12 Switch
15 Storage circuit
21, 22 Input transistor
23, 24 PMOS transistor
25 Resistor element
41 Input-side transistor
42 Output-side transistor
51 Output-side transistor
61 Output-side transistor
71 Input-side transistor
72 Output-side transistor
73 Resistor element
81 Reference element
82 Data element
100 Nonvolatile memory device
CMA, CMB Current mirror
DSw Sidewall
IV1 to IV4 Inverter
MT Memory element
MT1, MT2 Memory element
Md1 First data element
Md2 Second data element
Mr1 First reference element
Mr2 Second reference element
PM1, PM2 PMOS transistor
PMA to PMC PMOS transistor
R1, R2 Resistor element
Rr1 First reference resistor
Rr2 Second reference resistor
S1 to S4 Switch
SA Sense amplifier
SSw Sidewall
SW1 to SW4, SW8 Switch
SWA, SWB Switch

What is claimed is:

1. A nonvolatile memory device, comprising:
a memory element configured to perform program operation by trapping charges to a sidewall; and
a switch configured to widen a drain-source voltage of the memory element during the program operation, with polarity same as polarity during read operation.

2. The nonvolatile memory device according to claim 1, wherein
the memory element is an NMOS transistor, and
the switch is connected between an application end of a power supply voltage and a drain of the memory element.

3. The nonvolatile memory device according to claim 1, further comprising a first current mirror including a first input-side transistor, a first output-side transistor connected to a drain of the memory element, and a first resistor connected to the first input-side transistor.

4. The nonvolatile memory device according to claim 3, further comprising:
a second resistor,
a constant voltage circuit configured to make a voltage applied to the second resistor constant; and
a second current mirror including a second input-side transistor connected to the second resistor, and a second output-side transistor connected to the first input-side transistor.

5. The nonvolatile memory device according to claim 4, wherein the constant voltage circuit includes a drive transistor, the second resistor connected to the drive transistor, and a differential amplifier configured to drive the drive transistor based on a difference between a reference voltage and a sense voltage generated at a first node at which the drive transistor and the second resistor are connected.

6. The nonvolatile memory device according to claim 1, further comprising:
a third current mirror including a reference element and the data element,
a reference current generation unit connected to the data element and configured to generate a reference current; and
a storage circuit including the data element and the reference current generation unit.
wherein, in the storage circuit, data is read out based on magnitude relationship of a current flowing through the data element and the reference current.
